(19) United States
(12) Patent Application Publication
(10) Pub. No.: US 2022/0045180 A1
(43) Pub. Date: Feb. 10, 2022

(54) THIN-FILM TRANSISTOR FOR ELECTRO-STATIC DISCHARGE (ESD) PROTECTION AND ESD PROTECTION STRUCTURE

(71) Applicant: Shenzhen China Star Optoelectronics Semiconductor Display Technology Co., Ltd., Shenzhen (CN)

(72) Inventors: Xiang XIAO, Shenzhen (CN); Baixiang HAN, Shenzhen (CN)

(21) Appl. No.: 16/615,836

(22) PCT Filed: Jul. 22, 2019
(86) PCT No.: PCT/CN2019/097121

§ 371 Date: Nov. 22, 2019

(30) Foreign Application Priority Data
Apr. 29, 2019 (CN) 201910357615.2

(51) Int. Cl. H01L 29/417

(52) U.S. Cl. CPC H01L 29/41733; H01L 29/42384

(57) ABSTRACT

A thin-film transistor for electro-static discharge (ESD) protection and an ESD protection structure are provided. The thin-film transistor for ESD protection includes a substrate; an active layer disposed on the substrate; a gate insulating layer disposed on the active layer and on the substrate; a gate electrode disposed on the gate insulating layer and opposite to the active layer; an interlayer insulating layer disposed on the gate electrode and on the gate insulating layer; and a source electrode and a drain electrode disposed on the interlayer insulating layer and spaced apart. The source electrode has first ESD peaks, and the drain electrode has second ESD peaks facing first ESD peaks. The thin-film transistor for ESD protection has a thin-film transistor ESD path and a peak ESD path by disposing opposite ESD peaks on the source and drain electrodes, improving ESD efficiency, preventing circuits from being burnt, and guaranteeing product yield.

### BACKGROUND OF DISCLOSURE

### 1. Field of Disclosure

The present disclosure relates to the field of display technology, and more particularly, to a thin-film transistor for electro-static discharge (ESD) protection and an ESD protection structure.

### 2. Description of Related Art

With the development of display technology, flat panel display devices possess advantages of high image quality, power saving, thin body, wide application scope, etc. Thus, they have been widely applied in various consumer electronic products, such as mobile phones, televisions, personal digital assistants, digital cameras, notebooks, desktop computers, etc., and become the major display devices. Conventional flat panel display devices mainly include liquid crystal display (LCD) devices and organic light emitting diode display (OLED) devices.

For conventional flat panel display devices, an electro-static discharge (ESD) protection structure is disposed on a substrate in order to avoid static electricity. A conventional ESD protection structure adopts a thin-film transistor for ESD protection, having a gate floating structure, to discharge redundant electric charges. In a conventional ESD protection structure shown in FIGS. 1-2, a thin-film transistor 30 for ESD protection connects a signal line 10 and a common-voltage line 20. The thin-film transistor 30 for ESD protection includes a gate electrode 301, a source electrode 302, a drain electrode 303, and an active layer 304. A first coupling capacitor C10 is formed by an overlap between a part of the source electrode 302 and the gate electrode 301. A second coupling capacitor C20 is formed by an overlap between a part of the drain electrode 303 and the gate electrode 301. The source electrode 302 is electrically connected to a signal line 10. The drain electrode 303 is electrically connected to a common-voltage line 20. When static electricity accumulating on the signal line 10 or the common-voltage line 20 is excessive, the first coupling capacitor C10 or the second coupling capacitor C20 will be charged, causing a voltage of the gate electrode 301 of the thin-film transistor 30 for ESD protection to rise, and thus turning on the thin-film transistor 30 for ESD protection to discharge static electricity.

In order to ensure ESD effects, it needs to reduce as much as possible leakage current of the thin-film transistor 30 for ESD protection. The leakage current of the thin-film transistor 30 for ESD protection is related to a width of groove W and a length of groove L. The smaller the width of groove W, the less leakage current. The greater the length of groove L, the less leakage current. In order to reduce the leakage current, a width-and-length ratio (W/L) of the thin-film transistor 30 for ESD protection is designed as being very small (for example, 6:200) in conventional technologies. When static electricity occurs in lines, and when the static electricity is discharged through the thin-film transistor 30 for ESD protection, an excessively low width-and-length ratio will cause the discharge not to be rapid enough, burning circuits and thus reducing product yield.

### SUMMARY

The object of the present disclosure is to provide a thin-film transistor for electro-static discharge (ESD) protection, which can improve ESD efficiency, prevent circuits from being burnt, and guarantee product yield.

The object of the present disclosure is further to provide an ESD protection structure, which can improve ESD efficiency, prevent circuits from being burnt, and guarantee product yield.

In order to realize the above objects, the present disclosure provides a thin-film transistor for electro-static discharge (ESD) protection, including: a substrate; an active layer disposed on the substrate; a gate insulating layer disposed on the active layer and on the substrate; a gate electrode disposed on the gate insulating layer and opposite to the active layer; an interlayer insulating layer disposed on the gate electrode and on the gate insulating layer; and a source electrode and a drain electrode disposed on the interlayer insulating layer and spaced apart from each other.

The source electrode has a plurality of first ESD peaks, and the drain electrode has a plurality of second ESD peaks facing the plurality of first ESD peaks respectively.

The source electrode and the drain electrode are both U-shaped.

The source electrode has two first ESD peaks located at two ends of the source electrode respectively, and the drain electrode has two second ESD peaks located at two ends of the drain electrode respectively.

The active layer includes at least one material selected from a group consisting of amorphous silicon, polycrystalline silicon, and oxide semiconductor.

A first through hole and a second through hole pass through the interlayer insulating layer and the gate insulating layer, and the source electrode and the drain electrode pass through the first through hole and the second through hole respectively to be in contact with two ends of the active layer.

A first coupling capacitor is formed by an overlap between at least one part of the source electrode and the gate electrode. A second coupling capacitor is formed by an overlap between at least one part of the drain electrode and the gate electrode. A voltage is transmitted to the gate electrode through the first coupling capacitor or the second coupling capacitor, so that the thin-film transistor for ESD protection is turned on to discharge static electricity.

The present disclosure further provides an ESD protection structure, including a signal line, a common-voltage line, and a thin-film transistor for ESD protection.

The thin-film transistor for ESD protection includes a substrate, an active layer disposed on the substrate, a gate insulating layer disposed on the active layer and on the substrate, a gate electrode disposed on the gate insulating layer and opposite to the active layer, an interlayer insulating layer disposed on the gate electrode and on the gate insulating layer, and a source electrode and a drain electrode disposed on the interlayer insulating layer and spaced apart from each other.

The source electrode has a plurality of first ESD peaks, and the drain electrode has a plurality of second ESD peaks facing the plurality of first ESD peaks respectively.

The source electrode and the drain electrode are electrically connected to the signal line and the common-voltage line respectively.

The source electrode and the drain electrode are both U-shaped.

The source electrode has two first ESD peaks located at two ends of the source electrode respectively, and the drain electrode has two second ESD peaks located at two ends of the drain electrode respectively.

The active layer includes at least one material selected from a group consisting of amorphous silicon, polycrystalline silicon, and oxide semiconductor.

A first through hole and a second through hole pass through the interlayer insulating layer and the gate insulating layer, and the source electrode and the drain electrode pass through the first through hole and the second through hole respectively to be in contact with two ends of the active layer.

A first coupling capacitor is formed by an overlap between at least one part of the source electrode and the gate electrode. A second coupling capacitor is formed by an overlap between at least one part of the drain electrode and the gate electrode. A voltage is transmitted to the gate electrode through the first coupling capacitor or the second coupling capacitor, so that the thin-film transistor for ESD protection is turned on to discharge static electricity.

The beneficial effect of the present disclosure is that, the present disclosure provides a thin-film transistor for ESD protection, including: a substrate; an active layer disposed on the substrate; a gate insulating layer disposed on the active layer and on the substrate; a gate electrode disposed on the gate insulating layer and opposite to the active layer; an interlayer insulating layer disposed on the gate electrode and on the gate insulating layer; and a source electrode and a drain electrode disposed on the interlayer insulating layer and spaced apart from each other. The source electrode has a plurality of first ESD peaks, and the drain electrode has a plurality of second ESD peaks facing the plurality of first ESD peaks respectively. The thin-film transistor for ESD protection simultaneously has two ESD paths, such as a thin-film transistor discharge path and a peak discharge path, by disposing opposite ESD peaks on the source electrode and the drain electrode, thereby improving ESD efficiency, preventing circuits from being burnt, and guaranteeing product yield. The present disclosure further provides an ESD protection structure, which can improve ESD efficiency, prevent circuits from being burnt, and guarantee product yield.

### BRIEF DESCRIPTION OF DRAWINGS

In order to understand the features and the technical content of the present disclosure further, please refer to the detailed explanation and the accompanying drawings of the present disclosure as follows. However, the accompanying drawings are merely for reference and explanation without limiting the present disclosure.

The accompanying drawings are as follows:

FIG. 1 is a circuit diagram of a conventional electro-static discharge (ESD) protection structure.

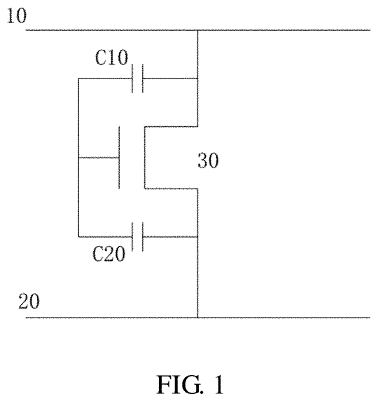

FIG. 2 is a top view of a thin-film transistor for ESD protection in a conventional ESD protection structure.

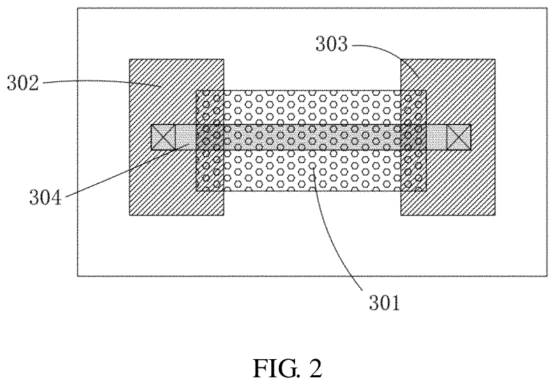

FIG. 3 is a top view of a thin-film transistor for ESD protection according to the present disclosure.

FIG. 4 is a cross-sectional view of a thin-film transistor for ESD protection according to the present disclosure.

FIG. 5 is a schematic structural diagram of an ESD protection structure according to the present disclosure.

FIG. 6 is an equivalent circuit diagram of an ESD protection structure according to the present disclosure.

### DETAILED DESCRIPTION OF EMBODIMENTS

In order to explain the technical solutions and the effects of the present disclosure further, they will be described in conjunction with preferred embodiments and the accompanying drawings of the present disclosure in detail below.

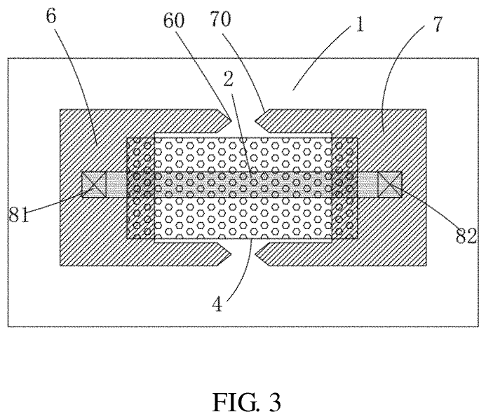

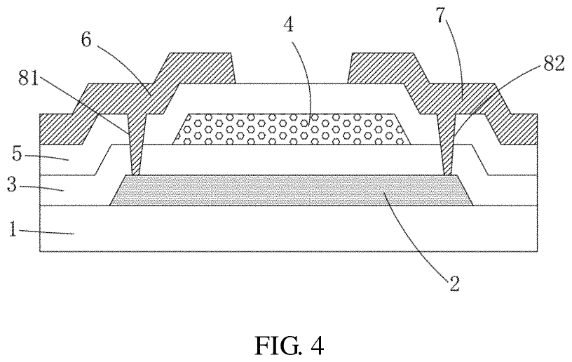

Please refer to FIGS. 3-4, the present disclosure provides a thin-film transistor for electro-static discharge (ESD) protection, including: a substrate 1; an active layer 2 disposed on the substrate 1; a gate insulating layer 3 disposed on the active layer 2 and on the substrate 1; a gate electrode 4 disposed on the gate insulating layer 3 and opposite to the active layer 2; an interlayer insulating layer 5 disposed on the gate electrode 4 and on the gate insulating layer 3; and a source electrode 6 and a drain electrode 7 disposed on the interlayer insulating layer 5 and spaced apart from each other.

The source electrode 6 has a plurality of first ESD peaks 60, and the drain electrode 7 has a plurality of second ESD peaks 70 facing the plurality of first ESD peaks 60 respectively.

Specifically, in a preferred embodiment of the present disclosure, the source electrode 6 and the drain electrode 7 are both U-shaped. The source electrode 6 has two first ESD peaks 60 located at two ends of the source electrode 6 respectively, and the drain electrode 7 has two second ESD peaks 70 located at two ends of the drain electrode 7 respectively.

Specifically, the active layer 2 includes at least one material selected from a group consisting of amorphous silicon, polycrystalline silicon, and oxide semiconductor. The oxide semiconductor can be indium gallium zinc oxide (IGZO).

Specifically, a first through hole 81 and a second through hole 82 pass through the interlayer insulating layer 5 and the gate insulating layer 3, and the source electrode 6 and the drain electrode 7 pass through the first through hole 81 and the second through hole 82 respectively to be in contact with two ends of the active layer 2.

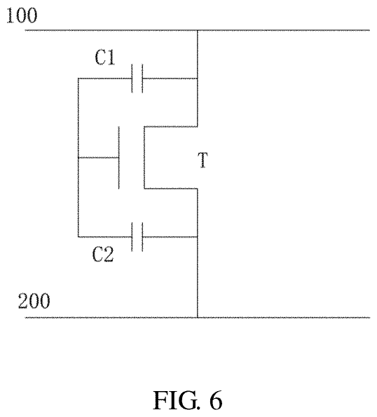

Specifically, in combination with FIG. 6, a first coupling capacitor C1 is formed by an overlap between at least one part of the source electrode 6 and the gate electrode 4. A second coupling capacitor C2 is formed by an overlap between at least one part of the drain electrode 7 and the gate electrode 4. A voltage is transmitted to the gate electrode 4 through the first coupling capacitor C1 or the second coupling capacitor C2, so that the thin-film transistor for ESD protection is turned on to discharge static electricity.

It needs to be stated that, the source electrode 6 and the drain electrode 7 of the thin-film transistor for ESD protection of the present disclosure have the first ESD peaks 60 and the second ESD peaks 70 respectively. The first ESD peaks 60 are disposed facing the second ESD peaks 70. When static electricity accumulating on lines is excessive, the first coupling capacitor C1 or the second coupling capacitor C2 will be charged, causing a voltage of the gate electrode 4 of the thin-film transistor for ESD protection to rise, and thus turning on the thin-film transistor for ESD protection to discharge static electricity. At the same time, the first ESD peaks 60 and the second ESD peaks 70 discharge static electricity through point discharge effect. Thus, the thin-film transistor for ESD protection simultaneously has two ESD paths, such as a thin-film transistor discharge path and a peak discharge path, thereby improving ESD efficiency, preventing circuits from being burnt, and guaranteeing product yield.

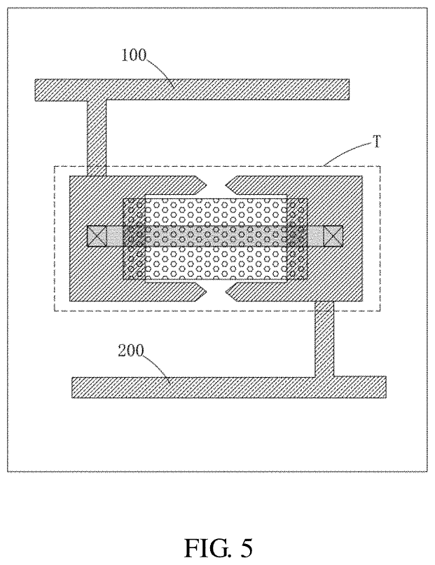

Please refer to FIGS. 3-6, the present disclosure further provides an electro-static discharge (ESD) protection structure, including a signal line 100, a common-voltage line 200, and a thin-film transistor T for ESD protection.

The thin-film transistor T for ESD protection includes a substrate 1, an active layer 2 disposed on the substrate 1, a gate insulating layer 3 disposed on the active layer 2 and on the substrate 1, a gate electrode 4 disposed on the gate insulating layer 3 and opposite to the active layer 2, an interlayer insulating layer 5 disposed on the gate electrode 4 and on the gate insulating layer 3, and a source electrode 6 and a drain electrode 7 disposed on the interlayer insulating layer 5 and spaced apart from each other.

The source electrode 6 has a plurality of first ESD peaks 60, and the drain electrode 7 has a plurality of second ESD peaks 70 facing the plurality of first ESD peaks 60 respectively.

The source electrode 6 and the drain electrode 7 are electrically connected to the signal line 100 and the common-voltage line 200 respectively.

Specifically, in some embodiments of the present disclosure, the source electrode 6 and the drain electrode 7 are both U-shaped. The source electrode 6 has two first ESD peaks 60 located at two ends of the source electrode 6 respectively, and the drain electrode 7 has two second ESD peaks 70 located at two ends of the drain electrode 7 respectively.

Specifically, the active layer 2 includes at least one material selected from a group consisting of amorphous silicon, polycrystalline silicon, and oxide semiconductor. The oxide semiconductor can be indium gallium zinc oxide (IGZO).

Specifically, a first through hole 81 and a second through hole 82 pass through the interlayer insulating layer 5 and the gate insulating layer 3, and the source electrode 6 and the drain electrode 7 pass through the first through hole 81 and the second through hole 82 respectively to be in contact with two ends of the active layer 2.

Specifically, a first coupling capacitor C1 is formed by an overlap between at least one part of the source electrode 6 and the gate electrode 4. A second coupling capacitor C2 is formed by an overlap between at least one part of the drain electrode 7 and the gate electrode 4. A voltage is transmitted to the gate electrode 4 through the first coupling capacitor C1 or the second coupling capacitor C2, so that the thin-film transistor for ESD protection is turned on to discharge static electricity.

Preferably, the signal line 100 is a scanning line (i.e., gate line) or a data line in display panels. The common-voltage line 200 is a corn-electrode line in display panels.

It needs to be stated that, the source electrode 6 and the drain electrode 7 of the thin-film transistor for ESD protection have the first ESD peaks 60 and the second ESD peaks 70 respectively. The first ESD peaks 60 are disposed facing the second ESD peaks 70. When static electricity accumulating on the signal line 100 or the common-voltage line 200 is excessive, the first coupling capacitor C1 or the second coupling capacitor C2 will be charged, causing a voltage of the gate electrode 4 of the thin-film transistor for ESD protection to rise, and thus turning on the thin-film transistor for ESD protection to discharge static electricity due to a connection between the signal line 100 and the common-voltage line 200. At the same time, the first ESD peaks 60 and the second ESD peaks 70 discharge static electricity through point discharge effect. Thus, the thin-film transistor for ESD protection simultaneously has two ESD paths, such as a thin-film transistor discharge path and a peak discharge path, thereby improving ESD efficiency, preventing circuits from being burnt, and guaranteeing product yield.

In conclusion, the present disclosure provides a thin-film transistor for ESD protection, including: a substrate; an active layer disposed on the substrate; a gate insulating layer disposed on the active layer and on the substrate; a gate electrode disposed on the gate insulating layer and opposite to the active layer; an interlayer insulating layer disposed on the gate electrode and on the gate insulating layer; and a source electrode and a drain electrode disposed on the interlayer insulating layer and spaced apart from each other. The source electrode has a plurality of first ESD peaks, and the drain electrode has a plurality of second ESD peaks facing the plurality of first ESD peaks respectively. The thin-film transistor for ESD protection simultaneously has two ESD paths, such as a thin-film transistor discharge path and a peak discharge path, by disposing opposite ESD peaks on the source electrode and the drain electrode, thereby improving ESD efficiency, preventing circuits from being burnt, and guaranteeing product yield. The present disclosure further provides an ESD protection structure, which can improve ESD efficiency, prevent circuits from being burnt, and guarantee product yield.

A person of ordinary skill in the art is able to make modifications or changes corresponding to the foregoing description based on the technical solutions and the technical ideas of the present disclosure, and all of these modifications and changes should be within the protective scope of the appended claims of the present disclosure.

What is claimed is:

1. A thin-film transistor for electro-static discharge (ESD) protection, comprising:
a substrate;
an active layer disposed on the substrate;
a gate insulating layer disposed on the active layer and on the substrate;
a gate electrode disposed on the gate insulating layer and opposite to the active layer;
an interlayer insulating layer disposed on the gate electrode and on the gate insulating layer; and
a source electrode and a drain electrode disposed on the interlayer insulating layer and spaced apart from each other;
wherein the source electrode has a plurality of first ESD peaks, and the drain electrode has a plurality of second ESD peaks facing the plurality of first ESD peaks respectively.

2. The thin-film transistor of claim 1, wherein the source electrode and the drain electrode are both U-shaped, the source electrode has two first ESD peaks located at two ends of the source electrode respectively, and the drain electrode has two second ESD peaks located at two ends of the drain electrode respectively.

3. The thin-film transistor of claim 1, wherein the active layer comprises at least one material selected from a group consisting of amorphous silicon, polycrystalline silicon, and oxide semiconductor.

4. The thin-film transistor of claim 1, wherein a first through hole and a second through hole pass through the interlayer insulating layer and the gate insulating layer, and the source electrode and the drain electrode pass through the first through hole and the second through hole respectively to be in contact with two ends of the active layer.

5. The thin-film transistor of claim 1, wherein a first coupling capacitor is formed by an overlap between at least one part of the source electrode and the gate electrode;
wherein a second coupling capacitor is formed by an overlap between at least one part of the drain electrode and the gate electrode; and
wherein a voltage is transmitted to the gate electrode through the first coupling capacitor or the second coupling capacitor, so that the thin-film transistor for ESD protection is turned on to discharge static electricity.

6. An electro-static discharge (ESD) protection structure, comprising a signal line, a common-voltage line, and a thin-film transistor for ESD protection;
wherein the thin-film transistor for ESD protection comprises a substrate, an active layer disposed on the substrate, a gate insulating layer disposed on the active layer and on the substrate, a gate electrode disposed on the gate insulating layer and opposite to the active layer, an interlayer insulating layer disposed on the gate electrode and on the gate insulating layer, and a source electrode and a drain electrode disposed on the interlayer insulating layer and spaced apart from each other;
wherein the source electrode has a plurality of first ESD peaks, and the drain electrode has a plurality of second ESD peaks facing the plurality of first ESD peaks respectively; and
wherein the source electrode and the drain electrode are electrically connected to the signal line and the common-voltage line respectively.

7. The ESD protection structure of claim 6, wherein the source electrode and the drain electrode are both U-shaped, the source electrode has two first ESD peaks located at two ends of the source electrode respectively, and the drain electrode has two second ESD peaks located at two ends of the drain electrode respectively.

8. The ESD protection structure of claim 6, wherein the active layer comprises at least one material selected from a group consisting of amorphous silicon, polycrystalline silicon, and oxide semiconductor.

9. The ESD protection structure of claim 6, wherein a first through hole and a second through hole pass through the interlayer insulating layer and the gate insulating layer, and the source electrode and the drain electrode pass through the first through hole and the second through hole respectively to be in contact with two ends of the active layer.

10. The ESD protection structure of claim 6, wherein a first coupling capacitor is formed by an overlap between at least one part of the source electrode and the gate electrode;
wherein a second coupling capacitor is formed by an overlap between at least one part of the drain electrode and the gate electrode; and
wherein a voltage is transmitted to the gate electrode through the first coupling capacitor or the second coupling capacitor, so that the thin-film transistor for ESD protection is turned on to discharge static electricity.
